(19) United States
(12) Patent Application Publication
(10) Pub. No.: US 2024/0311996 A1
(43) Pub. Date: Sep. 19, 2024

(54) METHOD AND APPARATUS FOR PERFORMING MACHINE LEARNING ENRICHED NON-DESTRUCTIVE EVALUATION

(71) Applicant: The Johns Hopkins University, Baltimore, MD (US)

(72) Inventors: Brendan P. Croom, Baltimore, MD (US); Michael Presley, Silver Spring, MD (US); Neil J. Joshi, Ellicott City, MD (US); Melissa A. Yates, Silver Spring, MD (US)

(73) Assignee: The Johns Hopkins University, Baltimore, MD (US)

(21) Appl. No.: 18/420,857

(22) Filed: Jan. 24, 2024

Related U.S. Application Data
(60) Provisional application No. 63/489,827, filed on Mar. 13, 2023.

(51) Int. Cl. G06T 7/00; G06F 30/23; G06T 5/50; G06V 10/46

(52) U.S. Cl. CPC G06T 7/0008; G06F 30/23; G06T 5/50; G06V 10/46; G06T 2207/10048; G06T 2207/10081; G06T 2207/10132; G06T 2207/20221; G06T 2207/30164

(57) ABSTRACT

A method of performing non-destructive evaluation (NDE) of a part or assembly may include receiving image and modeling data for the part or assembly from multiple sources, employing a machine learning model to fuse the image and modeling data into tabular data and fused image data associating predicted stress values with respective locations of the part or assembly, and linking the tabular data and fused image data together for display.

### CROSS-REFERENCE TO RELATED APPLICATION

This application claims priority to and the benefit of prior-filed, co-pending U.S. Provisional Application No. 63/489,827 filed on Mar. 13, 2023, the entire contents of which are hereby incorporated herein by reference.

### STATEMENT OF FEDERALLY SPONSORED RESEARCH OR DEVELOPMENT

This invention was made with Government support under contract number N00024-13-D-6400 awarded by the Naval Sea Systems Command (NAVSEA). The Government has certain rights in the invention.

### TECHNICAL FIELD

Example embodiments generally relate to techniques for performing non-destructive evaluation (NDE) of materials and assemblies for internal defects, and more particularly relate to the employment of machine learning as a tool for enhancing NDE while also improving efficiency.

### BACKGROUND

The use of X-ray computed tomography (XCT) is common in relation to non-destructive evaluation (NDE). In this regard, XCT is often employed to inspect manufactured materials and assemblies for internal defects. XCT can resolve three dimensional (3D) internal structures and discontinuities, which may affect the performance or mechanical reliability of a material. As one example context, XCT is well suited and commonly used for additive manufactured (AM) components.

AM systems include a variety of techniques that can manufacture complex 3D volumes from feedstock, including power bed fusion, fused filament fabrication, directed energy deposition, and other methods. Processing with these techniques can produce discontinuities that may affect performance, such as cracks, voids, delaminations, and other flaws. These flaws are common during processing, and occur stochastically throughout the part volume. Detection of these defects is essential to ensuring part performance.

Numerical simulations such as finite element method, finite volume method, and finite difference method can evaluate the mechanical stress concentrations around such discontinuities. These methods typically define a part geometry using a mesh, apply loads and boundary conditions to the model, and solve for the mechanical response using differential equations and equation solvers. Defects can be accounted for by incorporating them in the mesh (e.g., explicitly by morphing the mesh around the defects, or implicitly by modifying the constitutive response of local elements). These simulations are easy to interpret by tabulating and visually displaying the stress around defects. Moreover, the simulations permit easy identification of the maximum stress and potentially critical defects through visual display of the stress values, and enabling filtering of the results to isolate critical stressed regions.

However, computation of these results is demanding of time, resources and expertise, and cost scales with geometric complexity of the component. For instance, modifying the mesh to resolve small and intricately shaped defects is computationally intensive, and the additional elements make solving the problem slower. Thus, although numerical simulations are routinely used in the design and certification process of components and assemblies, and thus may be readily available for use to aid interpretation of NDE results, it may be desirable to provide a more powerful yet also more efficient way to achieve superior NDE result interpretation.

### BRIEF SUMMARY

Some non-limiting, example embodiments may enable the provision of a system that is capable of providing improved NDE with greater efficiency and speed.

In one example embodiment, a method of performing NDE of a part or assembly may be provided. The method may include receiving image and modeling data from multiple sources for the part or assembly, employing a machine learning model to fuse the image and modeling data into tabular data and fused image data associating predicted stress values with respective locations of the part or assembly, and linking the tabular data and fused image data together for display.

In another example embodiment, an apparatus for performing NDE of a part or assembly may be provided. The apparatus may include processing circuitry configured for receiving image and modeling data from multiple sources for the part or assembly, employing a machine learning model to fuse the image and modeling data into tabular data and fused image data associating predicted stress values with respective locations of the part or assembly, and linking the tabular data and fused image data together for display.

In yet another example embodiment, a method of fusing data of disparate types from multiple sources to provide enriched data for performing NDE of a part or assembly is provided. The method may include receiving simulation data associated with baseline geometry of the part or assembly and without any information regarding defects in the part or assembly, receiving defect data indicative of a location of each of one or more defects in the part or assembly without any information regarding simulated data, and modifying the simulation data based on the location of each of the one or more defects in the part or assembly to produce the enriched data.

### BRIEF DESCRIPTION OF THE SEVERAL VIEWS OF THE DRAWINGS

Having thus described the invention in general terms, reference will now be made to the accompanying drawings, which are not necessarily drawn to scale, and wherein:

FIG. 1 illustrates a functional block diagram of a system for performing NDE on a part or assembly according to an example embodiment;

FIG. 2 illustrates a more detailed block diagram of the system of FIG. 1 according to an example embodiment;

FIG. 3 illustrates a 2D example of data fusion via a machine learning data fusion module in accordance with an example embodiment;

FIG. 4 shows an interactive table displayed simultaneously with 2D fused image data in accordance with an example embodiment;

FIG. 5 illustrates a 3D example of data fusion via the machine learning data fusion module in accordance with an example embodiment;

FIG. 6 shows an interactive table displayed simultaneously with 3D fused image data in accordance with an example embodiment; and

FIG. 7 illustrates a block diagram of a method for performing NDE on a part or assembly in accordance with an example embodiment.

### DETAILED DESCRIPTION

Some non-limiting, example embodiments now will be described more fully hereinafter with reference to the accompanying drawings, in which some, but not all example embodiments are shown. Indeed, the examples described and pictured herein should not be construed as being limiting as to the scope, applicability or configuration of the present disclosure. Rather, these example embodiments are provided so that this disclosure will satisfy applicable legal requirements. As used herein, operable coupling should be understood to relate to direct or indirect connection that, in either case, enables functional interconnection of components that are operably coupled to each other. Like reference numerals refer to like elements throughout.

As noted above, XCT scans are already analyzed using finite element analysis to identify defects. However, this analysis is highly complex and therefore computationally expensive and very slow, thereby limiting its ultimate usefulness. Example embodiments employ machine learning to enhance analytical capabilities, but also do so faster and more efficiently. In this regard, machine learning (ML)-accelerated numerical simulation tools of example embodiments may predict stress concentrations around defects in parts (e.g., AM parts), and may further provide tools for integration into human-in-the-loop workflow that further aids XCT inspection and interpretation. In particular, example embodiments may employ a ML data fusion module to predict stress around defects in XCT scans, and identify or flag potentially critical defects. In this regard, example embodiments may further employ unique data processing and presentation tools that further enhance the interaction with human operators.

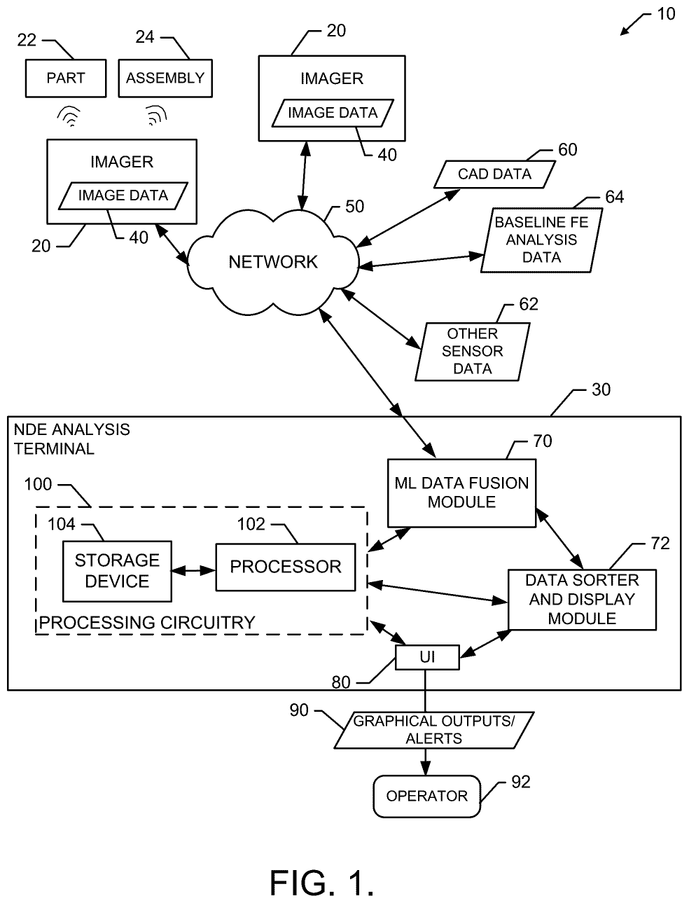

FIG. 1 illustrates a system 10 according to an example embodiment that may include one or more devices (e.g., imager 20) capable of obtaining inspection data on a part 22 or assembly 24. The inspection data may be provided to a non-destructive evaluation (NDE) analysis terminal 30. The example described herein will be related to an asset including a programmed computer or analysis terminal that is operably coupled to one or more of the imagers 20 to process inspection data received therefrom. The analysis terminal may therefore be referred to as the NDE analysis terminal 30. However, it should be appreciated that example embodiments may also apply to any asset including, for example, any programmable device that is capable of interacting with inspection data received in the manner described herein.

In some cases, the inspection data may include image data 40 that is three dimensional in the form of 3D image data descriptive of the volume of the part 22 or assembly 24. In this regard, each instance of the imager 20 may, for example, be embodied as a XCT imaging device and the image data 40 may be XCT inspection data that is reconstructed according to conventional means. Of note, whereas FIG. 1 illustrates two instances of the imager 20, it should be appreciated that the system 10 may operate with a single instance of the imager 20 or with a plurality of additional instances of the imager 20. Thus, the presentation of two instances of the imager 20 is only to illustrate the potential for multiplicity and should not be considered limiting.

In some example, particularly those with multiple instances of the imager 20, the multiple instances of the imager 20 may each be communicatively coupled to the NDE analysis terminal 30 via a network 50. The network 50 may be a wireless communication network 50 in some cases. However, in other examples, the network 50 may simply be formed by electronic switches or routers configured to provide the image data 40 (in parallel or in series) to the NDE analysis terminal 30 using wired connections. Combinations of wired and wireless connections are also possible. When only one imager 20 is operably coupled to the NDE analysis terminal 30, no network 50 may be employed at all and, in some cases, the imager 20 and the NDE analysis terminal 30 may be integrated into a single device. However, in a typical architecture, the imager 20 (or multiple imagers) may provide data to a computer terminal executing software, hardware or a combination or hardware and software components that configure the computer terminal into the NDE analysis terminal 30.

The NDE analysis terminal 30 may therefore include or otherwise be embodied as computing device (e.g., a computer, a network access terminal, laptop, server, a personal digital assistant (PDA), mobile phone, smart phone, tablet, or the like) capable of being configured to perform data processing as described herein. As such, for example, the NDE analysis terminal 30 may include (or otherwise have access to) memory for storing instructions or applications for the performance of various functions and a corresponding processor for executing stored instructions or applications. The NDE analysis terminal 30 may also include software and/or corresponding hardware for enabling the performance of the respective functions of the NDE analysis terminal 30 including, for example, the receipt or processing of the image data 40 and the generation and/or sharing of various content items including the outputs of the analyses performed on the image data 40 by the NDE analysis terminal 30.

The network 50 (if employed) may be a data network, such as a local area network (LAN), a metropolitan area network (MAN), a wide area network (WAN) (e.g., the Internet), and/or the like, which may couple one or more instances of the imager 20 to devices such as processing elements (e.g., personal computers, server computers or the like) and/or databases. Communication between the network 50, the imager(s) 20 and the devices or databases (e.g., servers) to which the imager(s) 20 are coupled may be accomplished by either wireline or wireless communication mechanisms and corresponding communication protocols. The protocols employed may include security, encryption or other protocols that enable the image data 40 to be securely transmitted without sacrificing privacy or operational security.

In some cases, the network 50 may also be operably coupled to other input devices or sources that may provide input data to the NDE analysis terminal 30. However, such input devices or sources could alternatively be directly operably coupled to the NDE analysis terminal 30. In the depicted example, the other input devices or sources may include computer aided design (CAD) data 60, other sensor data 62, and/or baseline finite element (FE) analysis data 64. The CAD data 60 may define a computer generated 3D model of the part 22 or assembly 24. The other sensor data 62 may include ultrasound image data, conventional image data from a visual camera, infrared (IR) image data from an IR camera, temperature data from a pyrometer, and/or the like. The baseline FE analysis data 64 may include numerical simulation data from conventional FE tools. Thus, for example, the baseline FE analysis data 64 may include FE stress prediction analysis previously determined by any means. Notably, the NDE analysis terminal 30 may fuse any and all of the inputs received, but can operate without all of the above-noted example inputs and instead with whatever inputs are provided thereto.

Whether directly supplied, or received via the network 50, the inputs to the NDE analysis terminal 30 may be fused together using unique tools and procedures in order to provide an output that is superior to existing numerical simulation methods, and that are also capable of being executed far more efficiently. In particular, the NDE analysis terminal 30 may include a machine learning (ML) data fusion module 70 that is primarily responsible for the data fusion aspect noted above, and a data sorter and display module 72 that is primarily responsible for generating output information that is both useful and easy to interface with. The data sorter and display module 72 may provide outputs to a user interface (UI) 80 that may in turn generate graphical outputs/alerts 90 to an operator 92.

Referring still to FIG. 1, an apparatus for provision of enriched imaging and numerical simulation for NDE using the image data 40 in accordance with an example embodiment is provided. However, it should be appreciated that the apparatus may also be capable of further providing alerting or warning functions views as well. Thus, the application specifically to monitoring for safety in terms of further identifying critical flaws (instead of just outputting data that may include evidence of such flaws without identifying them) as described herein should be appreciated as being a non-limiting example. The apparatus may be an embodiment of the NDE analysis terminal 30. As such, configuration of the apparatus as described herein may transform the apparatus into the NDE analysis terminal 30.

In an example embodiment, the apparatus may include or otherwise be in communication with processing circuitry 100 that is configured to perform data processing, application execution and other processing and management services according to an example embodiment of the present invention. In one embodiment, the processing circuitry 100, which may include a processor 102 and a storage device 104 (i.e., memory device with non-transitory memory), may be in communication with or otherwise control the UI 80 and the other components of the NDE analysis terminal 30 (e.g., the ML data fusion module 70 and the data sorter and display module 72). As such, the processing circuitry 100 may be embodied as a circuit chip (e.g., an integrated circuit chip) configured (e.g., with hardware, software or a combination of hardware and software) to perform operations described herein. However, in some embodiments, the processing circuitry 100 may be embodied as a portion of a server, computer, laptop, workstation or even one of various mobile computing devices. In situations where the processing circuitry 100 is embodied as a server or at a remotely located computing device, the UI 80 may be disposed at another device that may be in communication with the processing circuitry 100 via a network (e.g., network 50).

The UI 80 may be in communication with the processing circuitry 100 to receive an indication of a user input at the UI 80 and/or to provide an audible, visual, mechanical or other output to the user (e.g., graphical outputs/alerts 90). As such, the UI 80 may include, for example, a keyboard, a mouse, a joystick, a display, a touch screen, a microphone, a speaker, a cell phone, or other input/output mechanisms. In embodiments where the apparatus is embodied at a server or other network entity, the UI 80 may be limited or even eliminated in some cases. Alternatively, as indicated above, the UI 80 may be remotely located. In some cases, the UI 80 may also include a series of web pages or interface consoles generated to guide the user through various options, commands, flow paths and/or the like for control of or interaction with the NDE analysis terminal 30. The UI 80 may also include interface consoles or message generation capabilities to send instructions, warnings, alerts, etc., and/or to provide an output that clearly indicates a correlation between data determined in relation to the image data 40 and specific portions of the part 22 or assembly 24 to be of concern or otherwise indicative of a critical flaw at the location to which the data corresponds.

In an example embodiment, the storage device 104 may include one or more non-transitory storage or memory devices such as, for example, volatile and/or non-volatile memory that may be either fixed or removable. The storage device 104 may be configured to store information, data, applications, instructions or the like for enabling the apparatus to carry out various functions in accordance with example embodiments of the present invention. For example, the storage device 104 could be configured to buffer input data for processing by the processor 102. Additionally or alternatively, the storage device 104 could be configured to store instructions for execution by the processor 102. As yet another option, the storage device 104 may include one of a plurality of databases that may store a variety of files, contents or data sets, or structures used to embody one or more neural networks (e.g., a convolutional neural network (CNN) or other machine learning tools) capable of performing machine learning as described herein. Among the contents of the storage device 104, applications may be stored for execution by the processor 102 in order to carry out the functionality associated with each respective application.

The processor 102 may be embodied in a number of different ways. For example, the processor 102 may be embodied as various processing means such as a microprocessor or other processing element, a coprocessor, a controller or various other computing or processing devices including integrated circuits such as, for example, an ASIC (application specific integrated circuit), an FPGA (field programmable gate array), a hardware accelerator, or the like. In an example embodiment, the processor 102 may be configured to execute instructions stored in the storage device 104 or otherwise accessible to the processor 102. As such, whether configured by hardware or software methods, or by a combination thereof, the processor 102 may represent an entity (e.g., physically embodied in circuitry) capable of performing operations according to embodiments of the present invention while configured accordingly. Thus, for example, when the processor 102 is embodied as an ASIC, FPGA or the like, the processor 102 may be specifically configured hardware for conducting the operations described herein. Alternatively, as another example, when the processor 102 is embodied as an executor of software instructions, the instructions may specifically configure the processor 102 to perform the operations described herein.

In an example embodiment, the processor 102 (or the processing circuitry 100) may be embodied as, include or otherwise control the ML data fusion module 70 and the data sorter and display module 72, each of which may be any means such as a device or circuitry operating in accordance with software or otherwise embodied in hardware or a combination of hardware and software (e.g., processor 102 operating under software control, the processor 102 embodied as an ASIC or FPGA specifically configured to perform the operations described herein, or a combination thereof) thereby configuring the device or circuitry to perform the corresponding functions of the ML data fusion module 70 and the data sorter and display module 72, respectively, as described herein.

The ML data fusion module 70 may be configured to receive the image data 40 and other inputs (e.g., CAD data 60 and other sensor data 62) and perform data fusion thereon. As the image data 40 is XCT inspection data in this example, it can be appreciated that the fused data that results may be model of the part 22 or assembly 24 that shows predicted stress around various flaws or irregularities that may exist in the part 22 or assembly 24. In other words, to the extent the CAD data 60, the image data 40, and/or the sensor data 62 are 3D in nature, the fused data that results will also be 3D in nature. However, if instead the data fused is 2D in nature, the outputs may also be 2D in nature.

The ML data fusion module 70 may be configured to piece or fuse data together to calculate stress response around flaws or discontinuities of interest in the part 22 or assembly 24. The calculated stress response values are each correlated to a corresponding location within the part 22 or assembly 24. Thus, a result of the operation of the data fusion module 70 may include tabular data (e.g., stored in storage device 104) including a complete series of descriptions of locations (within the part 22 or assembly 24) and a corresponding stress response value that has been calculated for each respective one of the locations described. The tabular data may then be provided to the data sorter and display module 72 for further management and display.

The data sorter and display module 72 may be configured to generate the graphical outputs/alerts 90 via the UI 80 based on the tabular data generated by the ML data fusion module 70. Moreover, the data sorter and display module 72 may also enable interaction by the operator 92 with the graphical outputs/alerts 90 via the UI 80. In this regard, for example, as noted above, the tabular data may describe locations and corresponding calculated stress response values for each of the locations. The graphical outputs/alerts 90 may include an interactive table that includes one or more linking elements that allow the operator 92 to jump from the tabular data to the model or vice versa as described in greater detail below.

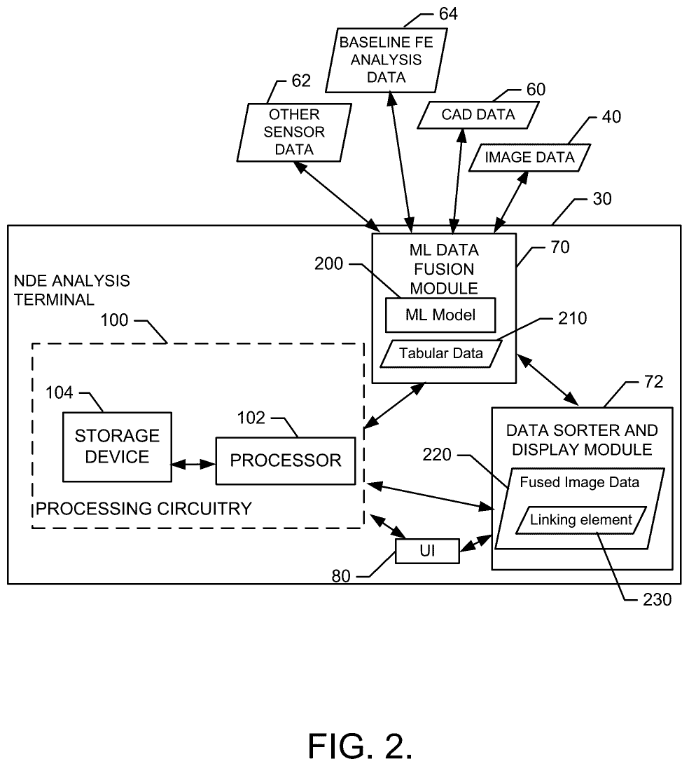

Turning to FIG. 2, a block diagram of the NDE analysis terminal 30 is shown in greater detail. In this regard, FIG. 2 further illustrates a ML model 200 located at (or otherwise accessible to the ML data fusion module 70, which generates the tabular data 210 based on fusing the inputs received thereat. The inputs may include the image data 40, the CAD data 60, the other sensor data 62, and the baseline FE analysis data 64. The ML model 200 may employ one or more instances of a neural network (e.g., a CNN), a support vector machine (SVM), Bayesian network, logistic regression, logistic classification, decision tree, ensemble classifier or other machine learning model to fuse the inputs into a fused data output that may be defined by or otherwise include the tabular data 210.

The ML model 200 may be supervised (identifying patterns in raw data upon which inference processes are desired to be performed via training examples) or unsupervised (identifying patterns in raw data upon which inference processes are desired to be performed without training examples). In an example embodiment, the ML model 200 may include a neural network of nodes where each node includes input values, a set of weights, and an activation function. The neural network node may calculate the activation function on the input values to produce an output value. The activation function may be a non-linear function computed on the weighted sum of the input values plus an optional constant. Neural network nodes may be connected to each other such that the output of one node is the input of another node. Moreover, neural network nodes may be organized into layers, each layer including one or more nodes. The neural network may be trained and update its internal parameters via backpropagation during training. A CNN may be a type of neural network that further adds one or more convolutional filters (e.g., kernels) that operate on the outputs of the preceding neural network layer to produce and output to then next layer. The convolutional filters may have a window in which they operate, which is spatially local. A node of a preceding layer may be connected to a node in the current layer if the node of the preceding layer is within the window. If not within the window, then the nodes are not connected.

In an example embodiment, training may occur via the provision of training data (e.g., training image data, training CAD data, training data from other sensors, etc.) along with target data that includes target FE analysis data. Thereafter, when inferences are to be drawn with respect to a new set of data including image and modeling data (e.g., the image data 40, the CAD data 60, the other sensor data 62, and the baseline FE analysis data 64) to provide an output that is the predicted FE data accounting for defects, and training backpropagation may be provided. Resulting fused image data and tabular data may then be used for display and interaction by the operator 92 to highlight critical flaws and permit deeper inspection by the operator 92.

Regardless of the specific form of the ML model 200, machine learning may be performed to perform inferences with respect to massively large volumes of data that would take normal computer processing very long periods of time to handle. The ML model 200 can handle massive volumes of data, and fuse the massive volumes of data into the tabular data 210 and fused image data 220 within seconds, whereas doing so with conventional processing tools (i.e., without ML) would take orders of magnitude longer periods of time. The ML model 200 therefore enables an acceleration of the processing needed to fuse diverse and massive bodies of data that, in this case, ultimately create an accurate picture of stress levels around flaws or discontinuities in a volume of material (e.g., additive manufactured material such as the part 22 or assembly 24). In particular, the ML model 200 fuses all of the data provided thereto (e.g., the image data 40, the CAD data 60, the other sensor data 62, and the baseline FE analysis data 64) into tabular data 210 that defines location specific calculated stress values throughout the volume of the part 22 or assembly 24. The tabular data 210 may then be used by the data sorter and display module 72 to correlate the locations of the tabular data 210 to corresponding fused image data 220 that may be generated to visually demonstrate areas of stress and amounts of stress graphically on a model of the part 22 or assembly 24. The tabular data 210 may also be ranked and displayed in rank order, thereby indicating locations where the highest (and therefore most concerning) stress levels are calculated. The fused image data 220 may represent the different stress levels that are calculated for various regions using color contours, or other display methods that display corresponding ranges of values in respective different colors, shades, shading, or patterns, etc. to facilitate differentiation visually by the operator 92. Moreover, the tabular data 210 and the fused image data 220 may be linked together so that clicking or selecting any entry or point in one, highlights or otherwise links to a corresponding portion of the other.

In some example embodiments, a linking element 230 may enable connection between the tabular data 210 and the fused image data 220 to providing this linking function. Thus, for example, the linking element 230 may provide for selection of any point in either the tabular data 210 or the fused image data 220 to identify the corresponding linked information in the other. Accordingly, again by way of example, if the operator 92 clicks on or selects a specific critical stress value or area in the fused image data 220, the corresponding data entry for the location selected will be highlighted in the tabular data 210. Alternatively, if the operator 92 selects a critical stress value from the tabular data 210, the view displayed on the UI 80 based on the fused image data 220 will be adjusted to show or highlight the corresponding location on the model of the part 22 or assembly 24.

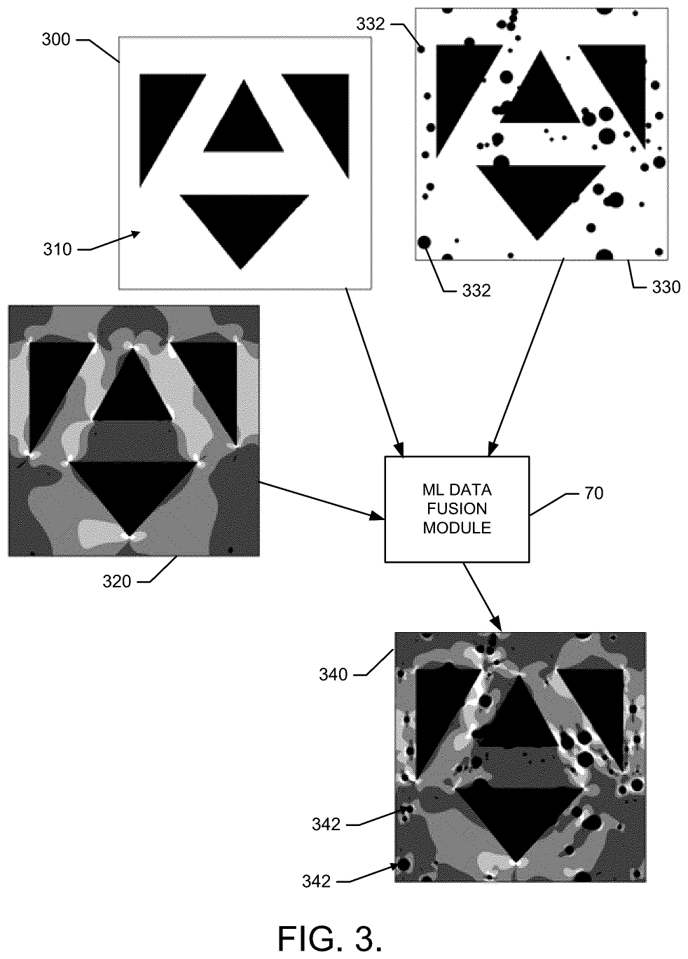

FIG. 3 shows a 2D example of data fusion according to an example embodiment. In this regard, the ML data fusion module 70 may receive CAD data 300 representing a 2D model of a part body 310, which is represented by the white space bounded within a black rectangle and having four separate void spaces (each triangular shaped in FIG. 3). The part itself may be made by additive manufacturing using any suitable material, and should be expected to have at least some flaws therein due to limitations associated with the additive manufacturing process. The ML data fusion module 70 may also receive a baseline FE analysis 320 that uses color or shade differences to indicate different levels (or ranges of levels) of stress calculated using conventional FE analysis tools applied to the model. In the baseline FE analysis 320, darker areas have lower calculated stress values and lighter areas have higher calculated stress values associated therewith. The ML data fusion module 70 may also receive an XCT image 330 in which dark spots 332 indicate flaws within the material of the part.

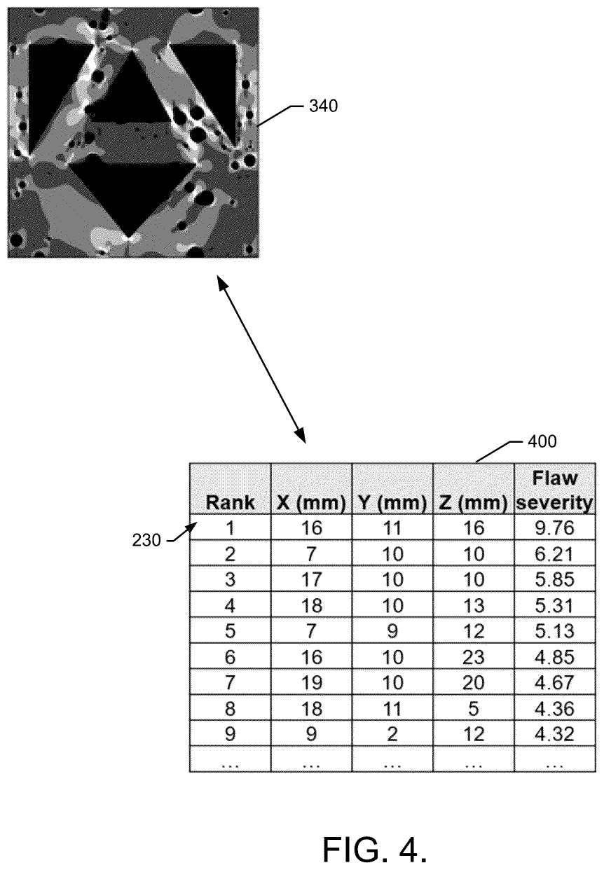

Upon receipt of these inputs, the ML data fusion module 70 may employ the ML model 200 discussed above to generate fused image data 340 showing flaws 342 as dark spots from the XCT image 330 and calculated stress levels around the flaws 342 again with ranges of such calculated stress levels being represented by color or shade contours. Although not shown in FIG. 3, the ML data fusion module 70 may also generate the tabular data 210, which may be stored in the storage device 104. The tabular data 210 may be used as a basis for generation and display of an interactive table 400 that is shown in FIG. 4. The interactive table 400 may be a graphical display of a portion of the tabular data 210 and, in some cases, may be provided in rank order.

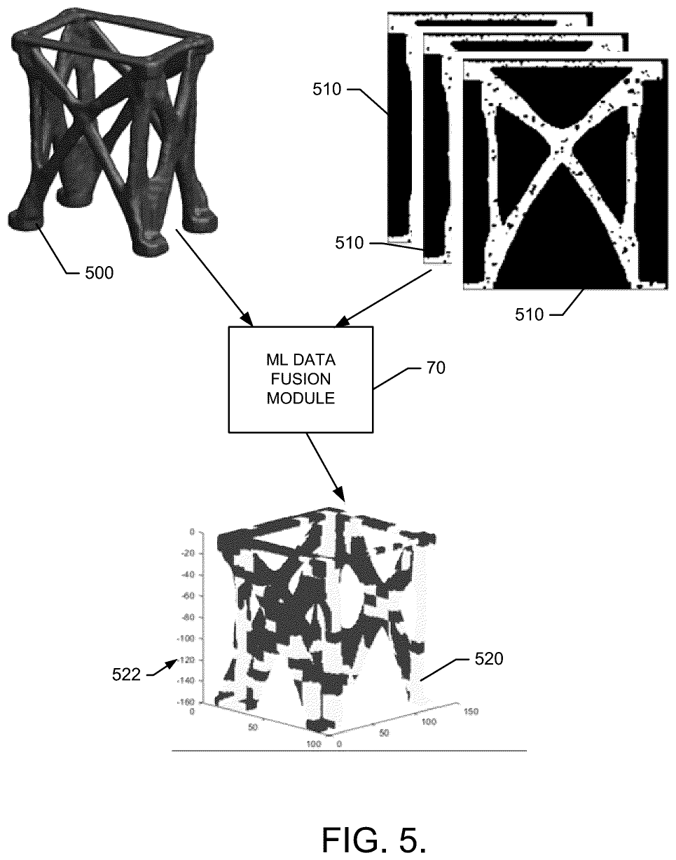

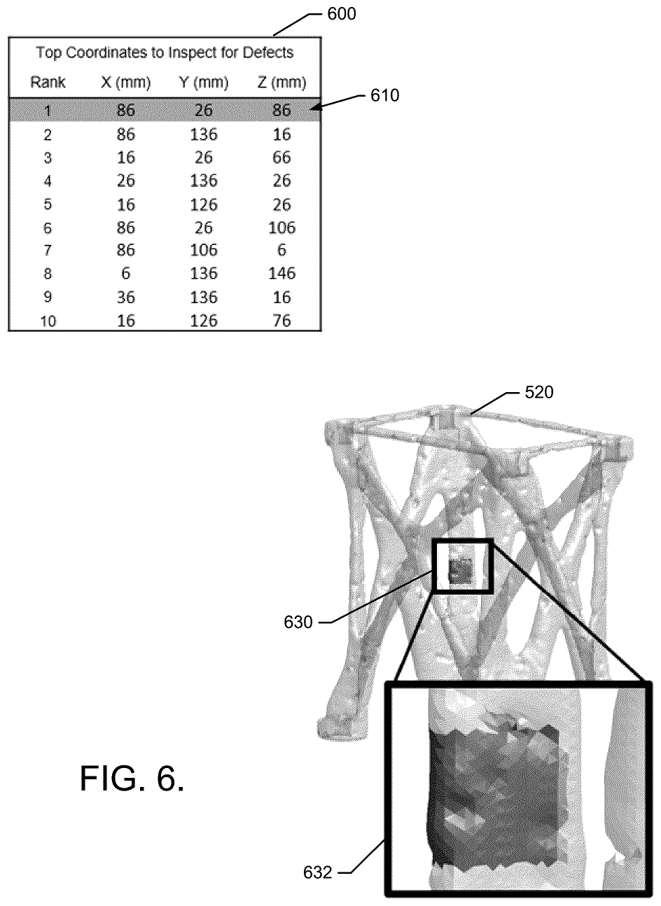

The rank order may be based on flaw severity, or the amount of calculated stress associated with a given flaw or location. In the interactive table 400 of FIG. 4, a location for each flaw for which severity of the calculated stress is above a given threshold may be recorded along with the amount of the calculated stress. The location is given in X, Y and Z coordinates in FIG. 4, but other locating paradigms could be used in other alternatives. The interactive table 400 may incorporate an instance of the linking element 230 for each row of data (i.e., for each ranked entry) in the interactive table 400. Thus, by clicking on any portion of a particular row, the corresponding linking element 230 may select the location of the flaw and also link to the same location in the fused image data 340. This linking is shown more clearly in the examples of FIGS. 5 and 6.

In this regard, FIG. 5 illustrates a 3D example of data fusion and FIG. 6 shows an interactive table displayed simultaneously with 3D fused image data in accordance with an example embodiment. Referring to FIGS. 5 and 6, the ML data fusion module 70 receives a 3D part rendering or model 500 (which may be an example of CAD data) and multiple XCT 2D orthogonal slices 510. The 3D part rendering or model 500 and the multiple XCT 2D orthogonal slices 510 may be fused together (perhaps with other inputs) to generate 3D fused image data 520. The 3D fused image data 520 may have reference coordinates 522 for each dimension, and may use color or shade contours as noted above to identify areas within different ranges of calculated stress. Moreover, some color or colors (or shade/shades) may identify stress levels above a threshold value (e.g., a critical value that merits attention and inspection by the operator 92).

In an example embodiment, the UI 80 may be used to display an interactive table 600 that may be generated and displayed based on the tabular data 210 as discussed above. The interactive table 600 may be displayed simultaneously (i.e., on the same screen) as the 3D fused image data 520. When the operator selects a row 610 of the interactive table 600 a corresponding region 630 in the part rendering of the 3D fused image data 520 may be highlighted. In some cases, an expansion window 632 may also be presented to show an enlarged view of the region 630 to further facilitate inspection by the operator 92. The linking elements 230 may be associated with each region 630 and may provide corresponding highlighting of rows when a given region is clicked on or selected, and may providing corresponding highlighting of regions when a given row or entry in the interactive table 600 is selected.

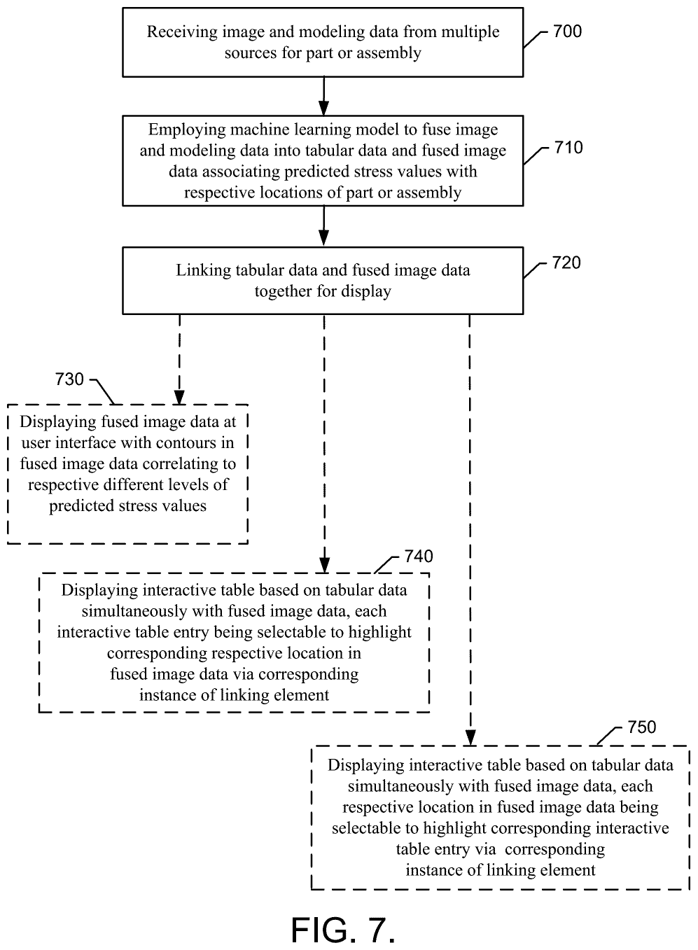

From a technical perspective, the NDE analysis terminal 30 described above may be used to support some or all of the operations described above. As such, the platform described in FIG. 1 may be used to facilitate the implementation of several computer program and/or network communication based interactions. As an example, FIG. 7 is an example of a flowchart of a method and program product according to an example embodiment of the invention. It will be understood that each block of the flowchart, and combinations of blocks in the flowchart, may be implemented by various means, such as hardware, firmware, processor, circuitry and/or other device associated with execution of software including one or more computer program instructions. For example, one or more of the procedures described above may be embodied by computer program instructions. In this regard, the computer program instructions which embody the procedures described above may be stored by a memory device of a user terminal and executed by a processor in the user terminal. As will be appreciated, any such computer program instructions may be loaded onto a computer or other programmable apparatus (e.g., hardware) to produce a machine, such that the instructions which execute on the computer or other programmable apparatus create means for implementing the functions specified in the flowchart block(s). These computer program instructions may also be stored in a computer-readable memory that may direct a computer or other programmable apparatus to function in a particular manner, such that the instructions stored in the computer-readable memory produce an article of manufacture which implements the functions specified in the flowchart block(s). The computer program instructions may also be loaded onto a computer or other programmable apparatus to cause a series of operations to be performed on the computer or other programmable apparatus to produce a computer-implemented process such that the instructions which execute on the computer or other programmable apparatus implement the functions specified in the flowchart block(s).

Accordingly, blocks of the flowchart support combinations of means for performing the specified functions and combinations of operations for performing the specified functions. It will also be understood that one or more blocks of the flowchart, and combinations of blocks in the flowchart, can be implemented by special purpose hardware-based computer systems which perform the specified functions, or combinations of special purpose hardware and computer instructions.

In an example embodiment, an apparatus for performing the method of FIG. 7 may include a processor (e.g., the processor 102) or processing circuitry configured to perform some or each of the operations (700-750) described below. The processor may, for example, be configured to perform the operations (700-750) by performing hardware implemented logical functions, executing stored instructions, or executing algorithms for performing each of the operations. In some embodiments, the processor or processing circuitry may be further configured to perform the additional operations or optional modifications to operations 700-750 that are discussed below.

The method may include receiving image and modeling data from multiple sources for the part or assembly at operation 700, employing employ a machine learning model to fuse the image and modeling data into tabular data and fused image data associating predicted stress values with respective locations of the part or assembly at operation 720, and linking the tabular data and fused image data together for display at operation 730.

The fusion aspect of the method of operation 720 may itself represent a method of fusing data of disparate types from multiple sources to provide enriched data for performing NDE of a part or assembly. The method may include receiving simulation data associated with baseline geometry of the part or assembly and without any information regarding defects in the part or assembly, receiving defect data indicative of a location of each of one or more defects in the part or assembly without any information regarding simulated data, and modifying the simulation data based on the location of each of the one or more defects in the part or assembly to produce the enriched data. Within this context, the simulation data may include simulation data indicative of stress estimates for all locations in the part or assembly and the defect data may include X-ray computed tomography (XCT) image data measuring presence, location and size information for each of the one or more defects in the part or assembly.

In some embodiments, the features or operations described above may be augmented or modified, or additional features or operations may be added. These augmentations, modifications and additions may be optional and may be provided in any combination. Thus, although some example modifications, augmentations and additions are listed below, it should be appreciated that any of the modifications, augmentations and additions could be implemented individually or in combination with one or more, or even all of the other modifications, augmentations and additions that are listed. As such, for example, the method may further include displaying the fused image data at a user interface with color or shade contours in the fused image data correlating to respective different levels of the predicted stress values at operation 730. Alternatively or additionally, the method may include the image and modeling data may include displaying an interactive table based on the tabular data simultaneously with the fused image data, where each entry in the interactive table is selectable to highlight a corresponding one of the respective locations in the fused image data via a corresponding one of the instances of the linking element at operation 740, and/or where each one of the respective locations in the fused image data is selectable to highlight a corresponding entry in the interactive table via a corresponding one of the instances of the linking element at operation 750. In an example embodiment, the image and modeling data may include NDE image data from multiple sources, and a two dimensional or three dimensional model of the part or assembly. In some cases, the image and modeling data may include XCT image data, baseline finite element analysis data, and CAD model data. In an example embodiment, the image and modeling data may further include other sensor data including at least one of a group of options including ultrasound image data, conventional image data from a visual camera, IR image data from an IR camera, and temperature data from a pyrometer. In some cases, employing the machine learning model may include employing supervised training and inference including backpropagation via a CNN to generate the tabular data and fused image data. In an example embodiment, linking the tabular data and fused image data together for display may include providing a plurality of instances of a linking element, each one of the plurality of instances of the linking element linking an entry in the tabular data to a portion of the fused image data associated with a corresponding one of the respective locations of the part or assembly. In an example embodiment, one or more of the color or shading contours may correspond to predicted stress higher than a threshold value.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Moreover, although the foregoing descriptions and the associated drawings describe exemplary embodiments in the context of certain exemplary combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. In cases where advantages, benefits or solutions to problems are described herein, it should be appreciated that such advantages, benefits and/or solutions may be applicable to some example embodiments, but not necessarily all example embodiments. Thus, any advantages, benefits or solutions described herein should not be thought of as being critical, required or essential to all embodiments or to that which is claimed herein. Although specific terms are employed herein, they are used in a generic and descriptive sense only and not for purposes of limitation.

What is claimed is:

1. A non-destructive evaluation (NDE) terminal comprising processing circuitry configured to:
receive image and modeling data for a part or assembly from multiple sources;
employ a machine learning model to fuse the image and modeling data into tabular data and fused image data associating predicted stress values with respective locations of the part or assembly; and
link the tabular data and fused image data together for display.

2. The NDE terminal of claim 1, wherein the image and modeling data comprises X-ray computed tomography (XCT) image data, baseline finite element analysis data, and computer aided design (CAD) model data.

3. The NDE terminal of claim 2, wherein the image and modeling data further comprises other sensor data including at least one of a group of options comprising:
ultrasound image data,
conventional image data from a visual camera,
infrared (IR) image data from an IR camera, and
temperature data from a pyrometer.

4. The NDE terminal of claim 1, wherein employing the machine learning model comprises employing supervised training and inference including backpropagation via a convolutional neural network (CNN) to generate the tabular data and fused image data.

5. The NDE terminal of claim 1, wherein linking the tabular data and fused image data together for display comprises providing a plurality of instances of a linking element, each one of the plurality of instances of the linking element linking an entry in the tabular data to a portion of the fused image data associated with a corresponding one of the respective locations of the part or assembly.

6. The NDE terminal of claim 5, wherein the processing circuitry is further configured to display the fused image data at a user interface with contours in the fused image data correlating to respective different levels of the predicted stress values.

7. The NDE terminal of claim 6, wherein
the contours are one of color contours and shade contours, and
one or more of the color or shade contours correspond to predicted stress higher than a threshold value.

8. The NDE terminal of claim 5, wherein the processing circuitry is further configured to display an interactive table based on the tabular data simultaneously with the fused image data, each entry in the interactive table being selectable to highlight a corresponding one of the respective locations in the fused image data via a corresponding one of the instances of the linking element.

9. The NDE terminal of claim 5, wherein the processing circuitry is further configured to display an interactive table based on the tabular data simultaneously with the fused image data, each one of the respective locations in the fused image data being selectable to highlight a corresponding entry in the interactive table via a corresponding one of the instances of the linking element.

10. A method of performing non-destructive evaluation (NDE) of a part or assembly, the method comprising:
receiving image and modeling data for the part or assembly from multiple sources;
employing a machine learning model to fuse the image and modeling data into tabular data and fused image data associating predicted stress values with respective locations of the part or assembly; and
linking the tabular data and fused image data together for display.

11. The method of claim 10, wherein the image and modeling data comprises X-ray computed tomography (XCT) image data, baseline finite element analysis data, and computer aided design (CAD) model data, and wherein the image and modeling data further comprises other sensor data including at least one of a group of options comprising:
ultrasound image data,
conventional image data from a visual camera,
infrared (IR) image data from an IR camera, and
temperature data from a pyrometer.

12. The method of claim 10, wherein employing the machine learning model comprises employing supervised training and inference including backpropagation via a convolutional neural network (CNN) to generate the tabular data and fused image data.

13. The method of claim 10, wherein linking the tabular data and fused image data together for display comprises providing a plurality of instances of a linking element, each one of the plurality of instances of the linking element linking an entry in the tabular data to a portion of the fused image data associated with a corresponding one of the respective locations of the part or assembly.

14. The method of claim 13, wherein the method further comprises displaying the fused image data at a user interface with contours in the fused image data correlating to respective different levels of the predicted stress values.

15. The method of claim 14, wherein
the contours are one of color contours and shade contours, and
one or more of the color or shade contours correspond to predicted stress higher than a threshold value.

16. The method of claim 13, wherein the method further comprises displaying an interactive table based on the tabular data simultaneously with the fused image data, each entry in the interactive table being selectable to highlight a corresponding one of the respective locations in the fused image data via a corresponding one of the instances of the linking element.

17. The method of claim 13, wherein the method further comprises displaying an interactive table based on the tabular data simultaneously with the fused image data, each one of the respective locations in the fused image data being selectable to highlight a corresponding entry in the interactive table via a corresponding one of the instances of the linking element.

18. The method of claim 10, wherein the image and modeling data comprises NDE image data from multiple sources, and a two dimensional or three dimensional model of the part or assembly.

19. A method of fusing data of disparate types from multiple sources to provide enriched data for performing non-destructive evaluation (NDE) of a part or assembly, the method comprising:
receiving simulation data associated with baseline geometry of the part or assembly and without any information regarding defects in the part or assembly;
receiving defect data indicative of a location of each of one or more defects in the part or assembly without any information regarding simulated data; and
modifying the simulation data based on the location of each of the one or more defects in the part or assembly to produce the enriched data.

20. The method of claim 19, wherein the simulation data comprises simulation data indicative of stress estimates for all locations in the part or assembly, and
wherein the defect data comprises X-ray computed tomography (XCT) image data measuring presence, location and size information for each of the one or more defects in the part or assembly.
